(19) United States
(12) Patent Application Publication
(10) Pub. No.: US 2025/0355093 A1
(43) Pub. Date: Nov. 20, 2025

(54) LIGHT RECEIVING DEVICE AND DISTANCE MEASURING DEVICE

(71) Applicant: Sony Semiconductor Solutions Corporation, Kanagawa (JP)

(72) Inventors: Kouzo Mawatari, Kanagawa (JP); Atsushi Horiguchi, Kanagawa (JP)

(21) Appl. No.: 18/866,758

(22) PCT Filed: May 8, 2023
(86) PCT No.: PCT/JP23/17274

§ 371 Date: Nov. 18, 2024

(30) Foreign Application Priority Data
Jun. 28, 2022 (JP) 2022-103156

(51) Int. Cl. G01S 7/4863; G01S 17/10

(52) U.S. Cl. CPC G01S 7/4863; G01S 17/10

(57) ABSTRACT

ESD surge protection that does not depend on pixel circuits is disclosed. In one example, a light receiving device includes an effective pixel including a light receiving element that detects presence or absence of photons and a readout circuit that processes a signal output from the light receiving element. A first terminal applies a predetermined voltage to the light receiving element, a second terminal applies a first power supply voltage to the readout circuit, and a protection circuit protects a light receiving element and a circuit element of the readout circuit from overvoltage. The protection circuit includes a light receiving element of a dummy pixel connected to the first terminal, and a diode element connected to the light receiving element of the dummy pixel in a polarity relationship in a reverse direction between the light receiving element of the dummy pixel and the second terminal.

### TECHNICAL FIELD

The present technology relates to a light receiving device. Specifically, the present invention relates to a light receiving device including a protection circuit that protects a circuit to be protected from electrostatic discharge (ESD), and a distance measuring device using the light receiving device.

### BACKGROUND ART

As one of methods for optically measuring a distance to a distance measuring object, a time of flight (ToF) method is known. In the ToF-based distance measuring device, a time of flight until the light emitted from a light source toward the distance measuring object is reflected by the distance measuring object and returns to the light receiving device is measured, and the distance from the distance measuring device to the distance measuring object is measured on the basis of the measured time of flight.

As described above, the ToF-based distance measuring device is equipped with the light receiving device that receives light reflected by the distance measuring object and returning. In this light receiving device, for example, a single photon avalanche diode (SPAD) element that detects the presence or absence of photons is used as a light receiving element.

Conventionally, a light receiving device is provided with a protection circuit that protects a readout circuit of a pixel including a light receiving element such as a SPAD element from an ESD surge voltage by forming an ESD surge current path in a pixel circuit that processes a signal of the light receiving element such as the SPAD element (see, for example, Patent Document 1).

### CITATION LIST

### Patent Document

Patent Document 1: WO 2021/090569 A

### SUMMARY OF THE INVENTION

### Problems to be Solved by the Invention

In the above-described conventional technique, in order to protect the readout circuit of the pixel including the light receiving element from ESD, a surge current path through which an ESD surge current flows is provided in the pixel circuit. When the surge current path exists in the pixel circuit as described above, the amount of current flowing through the surge current path, that is, the amount of current required for ESD surge protection depends on the pixel circuit.

The present technology has been made in view of such a situation, and an object thereof is to ensure an amount of current necessary for ESD surge protection without depending on a pixel circuit.

### Solutions to Problems

The present technology has been made to solve the above-described problems, and a first aspect thereof is a light receiving device including: an effective pixel including a light receiving element that detects presence or absence of photons and a readout circuit of a pixel which processes a signal output from the light receiving element; a dummy pixel including a light receiving element that does not contribute to detection of presence or absence of photons; a first terminal configured to apply a predetermined voltage to a light receiving element of the effective pixel and a light receiving element of the dummy pixel; a second terminal configured to provide a first power supply voltage to the readout circuit; and a protection circuit including a diode element connected between a light receiving element of the dummy pixel and the second terminal in a polarity relationship in a reverse direction with respect to a light receiving element of the dummy pixel, and protecting a light receiving element of the effective pixel and a circuit element of the readout circuit from overvoltage. Therefore, this brings about an effect that the amount of current required for ESD surge protection can be secured without depending on the circuit configuration, size, and the like of the pixel circuit.

Furthermore, in the first aspect, in the effective pixel, the readout circuit of the pixel may be formed in a pixel formation region paired with the light receiving element, and in the dummy pixel, the diode element may be formed in a pixel formation region corresponding to the pixel formation region of the effective pixel. Therefore, since the diode element can be formed as a diode element having a large size in the pixel formation region, a larger amount of current can be secured as the amount of current required for ESD surge protection.

Furthermore, in the first aspect, the light receiving element of the effective pixel and the light receiving element of the dummy pixel may be avalanche diodes, for example, single photon avalanche diodes. Therefore, this brings about an effect that a signal can be generated in response to reception of photons.

Furthermore, in the first aspect, as the diode element, a single photon avalanche diode of a dummy pixel adjacent to a dummy pixel to which the diode element belongs may be used. Therefore, there is no need to newly form a diode element, and a desired surge current path can be formed only by adding wiring or changing a circuit formation region.

Furthermore, in the first aspect, the light receiving device may include: a third terminal configured to apply a second power supply voltage to a readout circuit of the effective pixel; and at least one of a surge current path including a diode element connected to a light receiving element of the dummy pixel in a polarity relationship in a forward direction between the first terminal and the second terminal or a surge current path including a diode element connected to a light receiving element of the dummy pixel in a polarity relationship in a forward direction between the first terminal and the third terminal. Therefore, this brings about an effect that the high withstand voltage protection element provided in the pixel circuit can be made unnecessary.

Furthermore, in the first aspect, the readout circuit of the effective pixel may be configured using a thin film transistor. Therefore, this brings about an effect that an amount of current necessary for ESD surge protection can be secured even in a light receiving device having a pixel circuit including a thin film transistor.

Furthermore, a second aspect of the present technology is a light receiving device including: a first light receiving element; a quench element connected between a first node (electrode) that is an anode or a cathode of the first light receiving element and a node of a first power supply voltage; a transistor connected between a node of the first power supply voltage and a node of a second power supply voltage; a second light receiving element; and a diode element connected between a second node (electrode) that is an anode or a cathode of the second light receiving element and a node of the second power supply voltage and connected to the second light receiving element in a polarity relationship in a reverse direction. The first light receiving element and the second light receiving element receive a predetermined voltage at a node opposite to the first node and the second node. Therefore, this brings about an effect that the amount of current required for ESD surge protection can be secured without depending on the circuit configuration, size, and the like of the pixel circuit.

Furthermore, in the second aspect, the first light receiving element may be arranged in an effective pixel region, and the second light receiving element may be arranged in a dummy pixel region. Therefore, this brings about an effect that a surge current path (current path) for causing an ESD surge current to flow can be formed using the second light receiving element in the dummy pixel region.

Furthermore, in the second aspect, a first substrate including the first light receiving element and the second light receiving element, and a second substrate including the quench element, the transistor, and the diode element may be included. Therefore, this brings about an effect that a stacked semiconductor chip structure can be formed by the first substrate and the second substrate.

Furthermore, a third aspect of the present technology is a distance measuring device including: a light source unit that irradiates a distance measuring object with light; and a light receiving device that receives reflected light from the distance measuring object based on irradiation light from the light source unit. The light receiving device includes: an effective pixel including a light receiving element that detects presence or absence of photons and a readout circuit of a pixel which processes a signal output from the light receiving element; a dummy pixel including a light receiving element that does not contribute to detection of presence or absence of photons; a first terminal configured to apply a predetermined voltage to a light receiving element of the effective pixel and a light receiving element of the dummy pixel; a second terminal configured to apply a first power supply voltage to the readout circuit; and a protection circuit including a diode element connected between a light receiving element of the dummy pixel and the second terminal in a polarity relationship in a reverse direction with respect to a light receiving element of the dummy pixel, and protecting a light receiving element of the effective pixel and a circuit element of the readout circuit from overvoltage. Therefore, this brings about an effect that the amount of current required for ESD surge protection can be secured without depending on the circuit configuration, size, and the like of the pixel circuit.

### BRIEF DESCRIPTION OF DRAWINGS

FIG. 1 is a conceptual diagram illustrating a system configuration example of a ToF-based distance measuring system.

FIG. 2 is a block diagram illustrating an example of a basic configuration of the ToF-based distance measuring device.

FIG. 3 is a circuit diagram illustrating an example of a basic pixel circuit using a SPAD element.

FIG. 4 is a diagram for explaining a current-voltage characteristic of a PN junction of a SPAD element and a circuit operation of a pixel circuit using the SPAD element.

FIG. 5 is a perspective view schematically illustrating a semiconductor chip structure of the light receiving device.

FIG. 6 is a circuit diagram illustrating a configuration example of a pixel circuit including a protection circuit according to a reference example.

FIG. 7 is a circuit diagram schematically illustrating an embodiment of the present technology.

FIG. 8 is a perspective view schematically illustrating a configuration of a pixel array section in the light receiving device according to a first example of the embodiment of the present technology.

FIG. 9 is a perspective view schematically illustrating a wiring structure of a pixel array section in the light receiving device according to the first example.

FIG. 10 is a plan view schematically illustrating a configuration of a pixel array section in a light receiving device according to a second example in the embodiment of the present technology.

FIG. 11 is a plan view schematically illustrating a wiring structure of the pixel array section in the light receiving device according to the second example.

FIG. 12 is a perspective view schematically illustrating a configuration of a pixel array section in a light receiving device according to a third example in the embodiment of the present technology.

FIG. 13 is an explanatory diagram of two adjacent dummy pixels in the light receiving device according to the third example.

FIG. 14 is a circuit diagram schematically illustrating a circuit configuration example of a protection circuit of a light receiving device according to a fourth example in the embodiment of the present technology.

FIG. 15 is a diagram for explaining a configuration example in which three surge current paths are formed in the light receiving device according to the fourth example.

FIG. 16 is a perspective view schematically illustrating a wiring structure of the pixel array section in the light receiving device according to the fourth example.

FIG. 17 is a diagram for explaining a configuration example in which three surge current paths are formed in a light receiving device according to a fifth example in the embodiment of the present technology.

FIG. 18 is a circuit diagram schematically illustrating a circuit configuration example of a pixel circuit and a dummy pixel of a light receiving device according to a sixth example in the embodiment of the present technology.

FIG. 19 is a circuit diagram schematically illustrating a circuit configuration example of a pixel circuit and a dummy pixel of a light receiving device according to a seventh example in the embodiment of the present technology.

FIG. 20 is a block diagram illustrating a schematic configuration example of a vehicle control system.

FIG. 21 is an explanatory view illustrating an example of an installation position of an imaging section.

### MODE FOR CARRYING OUT THE INVENTION

Hereinafter, modes for carrying out the present technology (hereinafter referred to as embodiments) will be described. The description will be given in the following order.

1. ToF-based distance measuring system
1-1. System configuration example
1-2. Basic configuration example of distance measuring device
1-3. Basic pixel circuit example using SPAD element
1-4. Semiconductor chip structure of light receiving device
   1-4-1. Stacked semiconductor chip structure
   1-4-2. Flat semiconductor chip structure
1-5. Protection circuit according to reference example

2. Embodiments of the present technology
2-1. First example (example of stacked semiconductor chip structure)
2-2. Second example (example of flat semiconductor chip structure)
2-3. Third example (example in which SPAD element of dummy pixel adjacent to dummy pixel to which SPAD element belongs is used as diode element)
2-4. Fourth example (example in which high withstand voltage protection element provided in pixel circuit is unnecessary)
2-5. Fifth example (modification of fourth example: example using SPAD element of adjacent dummy pixel as diode element)
2-6. Sixth example (example in which pixel circuit includes thin film transistor)
2-7. Seventh example (example in which polarity of voltage applied to SPAD element is inverted in pixel circuit)

3. Modifications

4. Example of Application to Mobile Object

5. Configuration that present technology can employ

### <1. ToF-Based Distance Measuring System>

### System Configuration Example

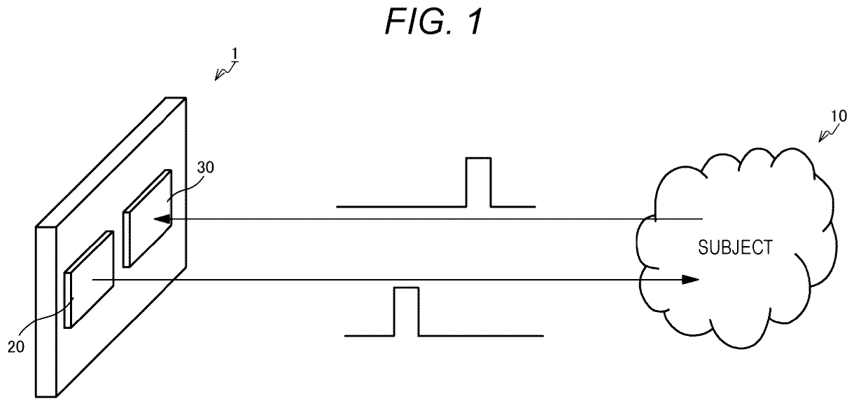

FIG. 1 is a conceptual diagram illustrating a system configuration example of a ToF-based distance measuring system. In the distance measuring system according to the present system configuration example, a distance measuring device 1 adopts the ToF method as a measurement method for measuring the distance to a subject 10 which is a distance measuring object, and includes a light source unit 20 and a light receiving device 30 in order to realize the distance measurement by the ToF method.

The light source unit 20 emits light toward the subject 10. Examples of the light emitted from the light source unit 20 toward the subject 10 include laser light having a peak wavelength in an infrared wavelength region. The light receiving device 30 includes a plurality of pixels, specifically, a plurality of pixels two-dimensionally arranged in a matrix (array), and detects (receives) reflected light reflected by the subject 10 and returned in units of pixels.

### Basic Configuration Example of Distance Measuring Device

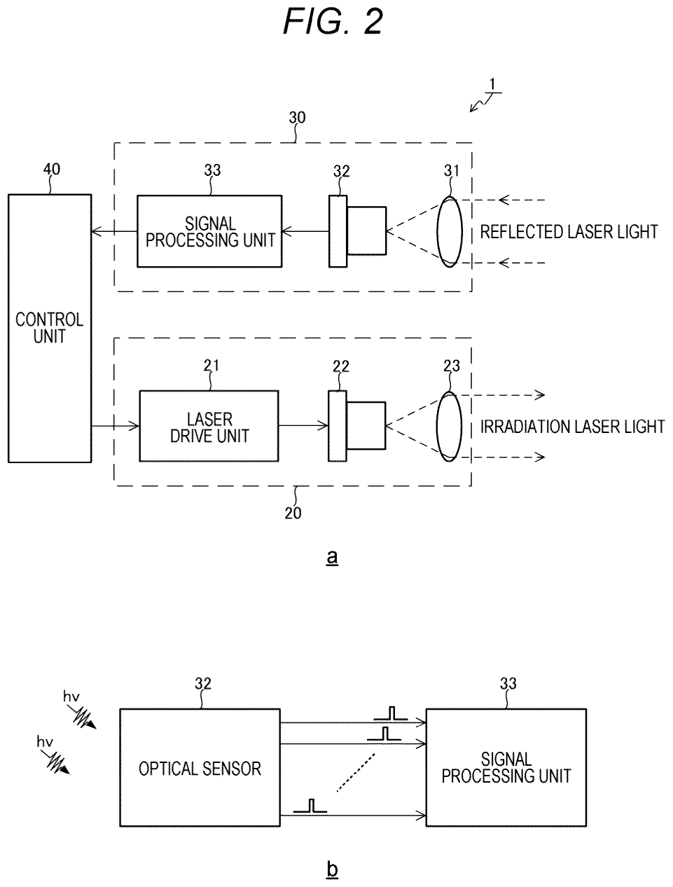

FIG. 2 illustrates a basic configuration example of the ToF-based distance measuring device 1. a of FIG. 2 illustrates an overall configuration of the distance measuring device 1, and b of FIG. 2 illustrates a configuration example on the light receiving device 30 side.

The light source unit 20 includes, for example, a laser drive unit 21, a laser light source 22, and a diffusion lens 23, and irradiates the subject 10, which is a distance measuring object, with laser light. The laser drive unit 21 drives the laser light source 22 under control of a control unit 40. The laser light source 22 uses, for example, a semiconductor laser as a light source, and emits pulsed laser light (hereinafter, it may be referred to as laser pulse light) under driving by the laser drive unit 21. The diffusion lens 23 diffuses the laser pulse light emitted from the laser light source 22, and irradiates the subject 10 with the laser pulse light.

The light receiving device 30 includes a light receiving lens 31, an optical sensor 32, and a signal processing unit 33, and receives reflected laser pulse light returned after the irradiation laser pulse light emitted from the light source unit 20 is reflected by the subject 10. The light receiving lens 31 focuses the reflected laser pulse light from the subject 10 on a light-receiving surface of the optical sensor 32. The optical sensor 32 includes a plurality of pixels, receives the reflected laser pulse light from the subject 10 through the light receiving lens 31 in units of pixels, and performs a photoelectric conversion. As the optical sensor 32, for example, a two-dimensional array sensor in which pixels including the light receiving elements are two-dimensionally arranged in a matrix (array) can be used.

The output signal of the optical sensor 32 is supplied to the control unit 40 via the signal processing unit 33. The control unit 40 is, for example, an application processor including a processor such as a central processing unit (CPU), controls the light source unit 20 and the light receiving device 30, and measures the time until the pulsed laser light emitted from the light source unit 20 toward the subject 10 is reflected by the subject 10 and returns. The distance to the subject 10 can be obtained on the basis of the measured time.

Then, in the distance measuring device 1 in the present example, the optical sensor 32 may include a sensor including an element that detects the presence or absence of photons, for example, a single photon avalanche diode (SPAD) element as the light receiving element of the pixel. That is, the light receiving device 30 of the distance measuring device 1 exemplified here has a configuration using the SPAD element as the light receiving element of the pixel. The SPAD element operates in a so-called Geiger mode in which the element is operated at a reverse voltage exceeding a breakdown voltage V_{BD}.

Note that, here, the SPAD element is exemplified as the light receiving element of the pixel, but the light receiving element is not limited to the SPAD element. That is, as the light receiving element of the pixel, in addition to the SPAD element, various elements, such as an avalanche photodiode (APD) and a silicon photomultiplier (SiPM), that operate in the Geiger mode can be used.

### Basic Pixel Circuit Example Using SPAD Element

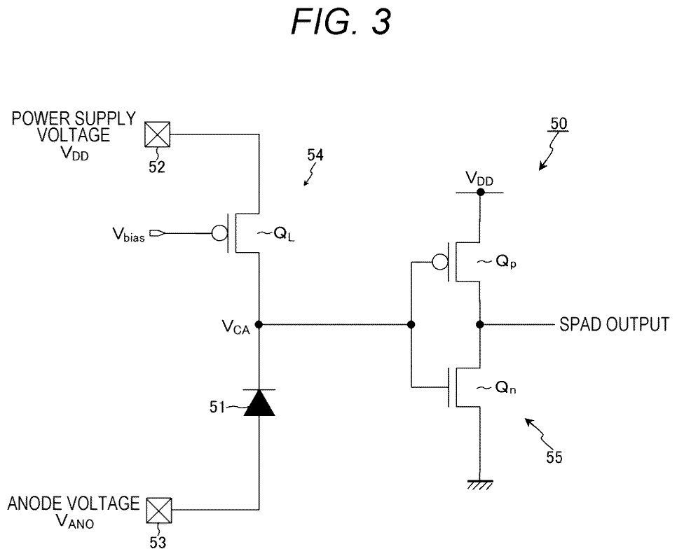

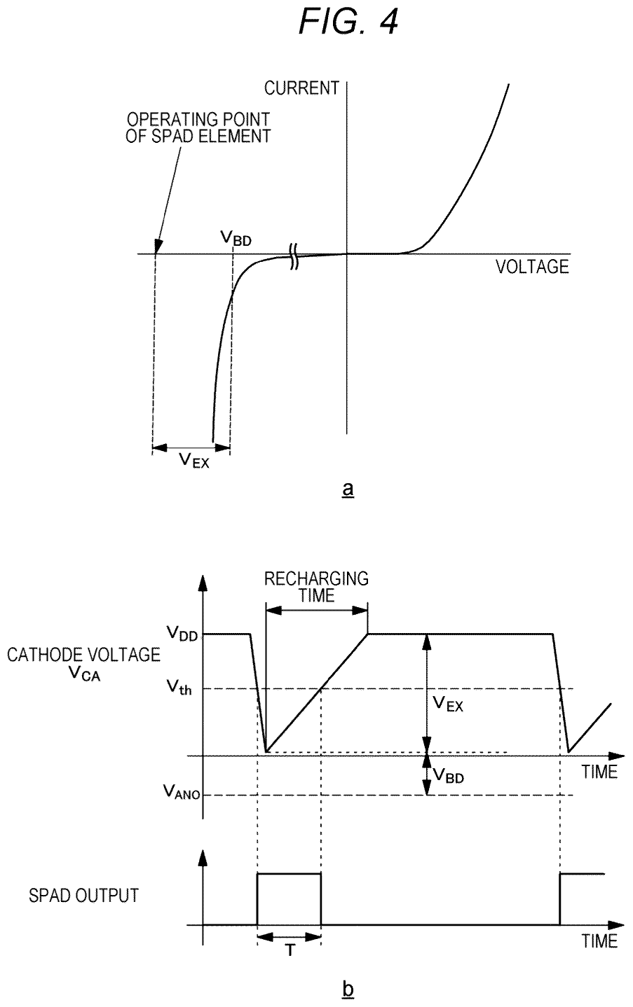

Here, a basic pixel circuit in the light receiving device 30 using the SPAD element will be described with reference to FIGS. 3 and 4.

FIG. 3 is a circuit diagram illustrating an example of a configuration of a basic pixel circuit in the light receiving device 30 using the SPAD element. Here, a basic configuration of one pixel is illustrated. a of

FIG. 4 is a characteristic diagram illustrating a current-voltage characteristic of a PN junction of the SPAD element, and b of FIG. 4 is a waveform diagram for explaining a circuit operation of a pixel circuit using the SPAD element.

In a basic pixel circuit (pixel readout circuit) of a pixel 50 using the SPAD element, a cathode electrode of an SPAD element 51 is connected to a terminal 52 via a quench element 54 including, for example, a P-type MOS transistor Q_{L}. A power supply voltage V_{DD} on the high potential side is applied to the terminal 52. The terminal 52 is an example of a third terminal described in the claims, and provides the power supply voltage V_{DD} on the high potential side, which is a second power supply voltage, to a readout circuit including the quench element 54.

An anode electrode of the SPAD element 51 is connected to a terminal 53. A predetermined voltage, specifically, a large negative voltage at which avalanche multiplication occurs is provided as an anode voltage V_{ANO} to the terminal 53. The terminal 53 is an example of a first terminal described in the claims, and applies the anode voltage V_{ANO} to the anode electrode of the SPAD element 51.

In the quench element 54, a predetermined bias voltage V_{bias} is applied to the gate electrode of the P-type MOS transistor Q_{L}. The bias voltage V_{bias} causes the MOS transistor Q_{L} to operate as a desired current source.

Then, a cathode voltage V_{CA} of the SPAD element 51 is derived as a SPAD output (pixel output) via a CMOS inverter 55 including a P-type MOS transistor Qₚ and an N-type MOS transistor Qₙ. The CMOS inverter 55 can be referred to as a comparison circuit (comparator) using a threshold voltage Vₜₕ as a comparison reference, or can be referred to as a waveform shaping circuit that shapes the waveform of the cathode voltage V_{CA} that is the output of the SPAD element 51 using the threshold voltage Vₜₕ as a reference.

A voltage equal to or higher than the breakdown voltage V_{BD} is applied to the SPAD element 51. An excess voltage that exceeds the breakdown voltage V_{BD} is referred to as an excess bias voltage V_{EX}. The characteristics of the SPAD element 51 change depending on how large the excess bias voltage V_{EX} is applied with respect to the voltage value of the breakdown voltage V_{BD}.

a of FIG. 4 illustrates a current-voltage characteristic of the PN junction of the SPAD element 51 operating in the Geiger mode. Specifically, a of the drawing illustrates the relationship between the breakdown voltage V_{BD}, the excess bias voltage V_{EX}, and the operating point of the SPAD element 51.

### Example of Circuit Operation of Pixel Circuit Using SPAD Element

Next, an example of a circuit operation of the pixel circuit having the above configuration will be described with reference to a waveform diagram in b of FIG. 4.

In a state where no current flows through the SPAD element 51, a voltage with a value of (V_{DD}−V_{ANO}) is applied to the SPAD element 51. The voltage value (V_{DD}−V_{ANO}) applied to the SPAD element 51 is (V_{BD}+V_{EX}). Then, a dark count rate (DCR) and electrons generated by light irradiation at the PN junction of the SPAD element 51 generate avalanche multiplication, and an avalanche current is generated.

When the cathode voltage V_{CA} decreases and the voltage between the terminals of the SPAD element 51 reaches the breakdown voltage V_{BD} of the PN junction diode, the avalanche current stops. Then, electrons generated and accumulated by avalanche multiplication are discharged through the quench element 54 (for example, the P-type MOS transistor Q_{L}). This discharge increases the cathode voltage V_{CA}. Then, the cathode voltage V_{CA} of the SPAD element 51 is recovered to the power supply voltage V_{DD}, and returns to the initial state again.

When light is incident on the SPAD element 51 and even one electron-hole pair is generated, it becomes a seed and an avalanche current is generated. As a result, even when one photon is incident, detection can be performed with a certain photon detection efficiency (PDE).

The above operation is repeated. Then, in this series of operations, the cathode voltage V_{CA} of the SPAD element 51 is waveform-shaped by the CMOS inverter 55, and a pulse signal having a pulse width T with the arrival time of one photon as a start point becomes a SPAD output (pixel output).

### Semiconductor Chip Structure of Light Receiving Device

As the semiconductor chip structure of the light receiving device 30 having the above configuration, a flat semiconductor chip structure and a stacked semiconductor chip structure can be applied as an example. The stacked semiconductor chip structure and the flat semiconductor chip structure will be schematically described below.

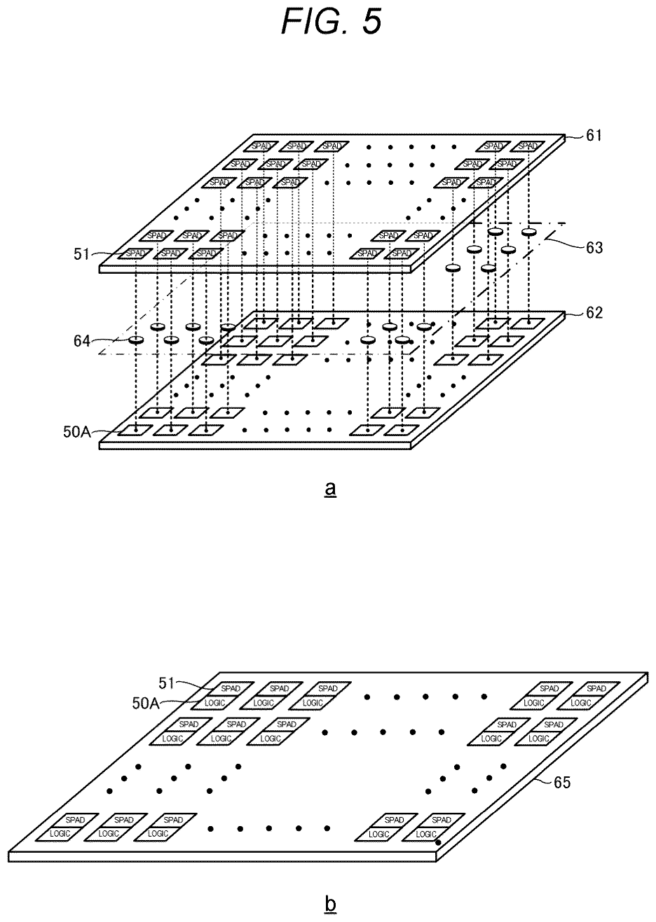

FIG. 5 is a perspective view schematically illustrating a semiconductor chip structure of the light receiving device 30. a of FIG. 5 schematically illustrates a stacked semiconductor chip structure, and b of FIG. 5 schematically illustrates a flat semiconductor chip structure.

### Stacked Semiconductor Chip Structure

As illustrated in a of FIG. 5, the stacked semiconductor chip structure, a so-called stacked structure, has a chip structure in which at least two semiconductor substrates (chips) of a first semiconductor substrate 61 and a second semiconductor substrate 62 are stacked.

In this stacked semiconductor chip structure, the first semiconductor substrate 61 is a sensor chip in which the SPAD elements 51 as an example of the light receiving element are two-dimensionally arranged in a matrix. The second semiconductor substrate 62 is a logic chip in which the readout circuits (logic circuits) 50A of the pixels 50 paired with the SPAD elements 51 in the first semiconductor substrate 61 are two-dimensionally arranged in a matrix corresponding to the SPAD elements 51.

The SPAD element 51 on the first semiconductor substrate 61 and the readout circuit (logic circuit) 50A on the second semiconductor substrate 62 are electrically connected via a bonding portion 64 formed in a wiring layer 63 interposed between the first semiconductor substrate 61 and the second semiconductor substrate 62. As an example of the bonding portion 64 of the wiring layer 63, a Cu—Cu bonding for directly bonding Cu electrodes can be exemplified.

According to the stacked semiconductor chip structure described above, a process suitable for manufacturing the SPAD element 51 can be applied to the first semiconductor substrate 61, and a process suitable for manufacturing the readout circuit 50A of the pixel 50 can be applied to the second semiconductor substrate 62. That is, the process can be optimized in manufacturing the light receiving device 30.

### Flat Semiconductor Chip Structure

As illustrated in b of FIG. 5, the flat semiconductor chip structure, that is, the flat structure, is a chip structure in which the SPAD element 51 and the readout circuit 50A of the pixel 50 are formed on the same semiconductor substrate 65. Specifically, the SPAD element 51 and the readout circuit 50A of the pixel 50 are paired and two-dimensionally arranged in a matrix on the same semiconductor substrate 65.

As described above, the semiconductor chip structure of the light receiving device 30 used in the distance measuring device 1 may be a stacked semiconductor chip structure in which the PAD element 51 and the readout circuit 50A of the pixel 50 are formed and stacked on separate semiconductor substrates, or may be a flat semiconductor chip structure in which both are formed on the same semiconductor substrate.

### Regarding Protection Circuit According to Reference Example

Here, a state of a protection circuit that protects a readout circuit of the pixel 50 including the SPAD element 51 from an ESD surge voltage will be described as a protection circuit according to a reference example. The protection circuit according to the reference example is a protection circuit provided in the pixel circuit.

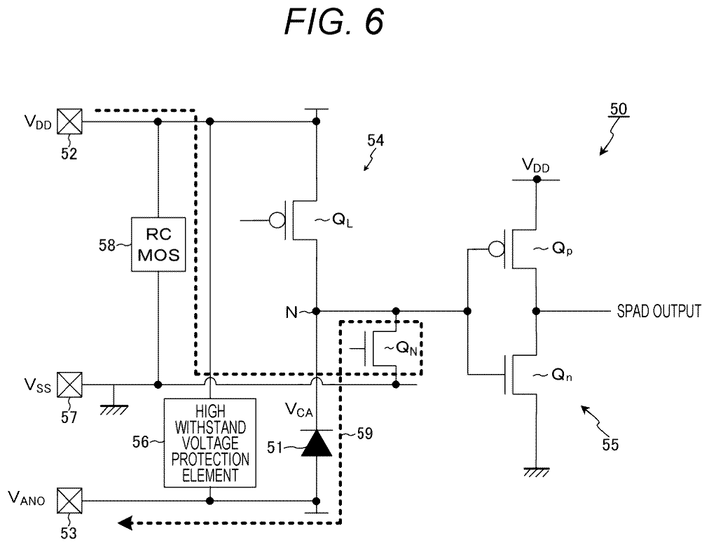

FIG. 6 is a circuit diagram illustrating a configuration example of a pixel circuit including a protection circuit according to a reference example. As illustrated in FIG. 6, a high withstand voltage protection element 56 for protecting the readout circuit of the pixel 50 including the SPAD element 51 from the ESD surge voltage is connected between the terminal 52 to which the power supply voltage V_{DD} on the high potential side is provided and the terminal 53 to which the anode voltage V_{ANO} is provided.

In addition to the high withstand voltage protection element 56, a logic circuit protection circuit (RCMOS) 58 is provided to protect a logic circuit (pixel readout circuit) including the CMOS inverter 55 and the like. The logic circuit protection circuit 58 is connected between the terminal 52 to which the power supply voltage V_{DD} on the high potential side is provided and a terminal 57 to which the power supply voltage V_{SS} (for example, 0 V) on the low potential side is provided.

Furthermore, an N-type MOS transistor Q_{N} is connected between a node N, which is a connection node between the cathode electrode of the SPAD element 51 and the quench element 54, and the terminal 57 to which the power supply voltage V_{SS} on the low potential side is applied. The terminal 57 is an example of a second terminal described in the claims, and provides a power supply voltage V_{SS} on the low potential side, which is a first power supply voltage, to a logic circuit (pixel readout circuit) including the N-type MOS transistor Q_{N}.

In the protection circuit according to the above-described reference example, the high withstand voltage protection element 56 protects the readout circuit of the pixel 50 including the SPAD element 51 from the ESD surge voltage by releasing the ESD surge voltage entering at the time of assembling or manufacturing the light receiving device 30. The high withstand voltage protection element 56 should not operate at a voltage equal to or lower than the normal operation voltage of the SPAD element 51, and needs to operate at a voltage higher than the normal operation voltage.

That is, when the breakdown voltage of the SPAD element 51 is V_{BD} and the excess bias voltage is V_{EX}, it is necessary to design the operation start voltage (ON voltage) V_{ON} of the high withstand voltage protection element 56 so as to satisfy the condition of |V_{ON}|>|V_{BD}+V_{EX}|. Therefore, since the breakdown region is included in the normal operation of the SPAD element 51, even if a current flows through the SPAD element 51, the high withstand voltage protection element 56 should not operate and does not contribute to protection of the readout circuit of the pixel 50 including the SPAD element 51.

Therefore, the high withstand voltage protection element 56 functions as a protection element against the ESD surge voltage entering from the terminal 53, that is, the ESD surge voltage in the forward direction of the SPAD element 51, but does not function as a protection element against the ESD surge voltage entering from the terminal 52, that is, the ESD surge voltage in the reverse direction of the SPAD element 51.

Therefore, the protection circuit according to the reference example has a configuration in which a surge current path 59 indicated by a bold dotted line in FIG. 6, that is, a current path of the terminal 52→the parasitic diode of the N-type MOS transistor Q_{N}→the SPAD element 51→the terminal 53 is formed, and a surge current flows through the SPAD element 51 itself, thereby protecting the readout circuit of the pixel 50 including the SPAD element 51 from the ESD surge voltage in the reverse direction of the SPAD element 51.

As described above, the surge current path 59 indicated by a bold dotted line in FIG. 6 is integrated into the parasitic diode of the N-type MOS transistor Q_{N} and the SPAD element 51 (in the reverse direction). Then, the current capability per pixel is determined by the smaller allowable current Iₘₐₓ of the N-type MOS transistor Q_{N} and the SPAD element 51 forming the surge current path 59.

Note that, although FIG. 6 illustrates a pixel circuit for one pixel, a plurality of pixels (a plurality of systems) is actually connected in parallel. Then, even if the breakdown voltage V_{BD} of the SPAD element 51 and the N-type MOS transistor ON forming the surge current path 59 varies, they operate in parallel in transient charge transfer at the time of an ESD event. That is, the electric charge that can flow into one system is limited due to high impedance, and each system is sequentially turned on and operated in parallel. Therefore, the ESD surge current flowing through the surge current path 59 is divided among a large number of pixels.

As described above, the protection circuit according to the reference example has a configuration in which the surge current path 59 exists in the pixel circuit. Here, a problem with the recent miniaturization of the SPAD element 51 is the size of the pixel circuit (logic circuit) paired with the SPAD element 51, and how small the size can be is an urgent problem. In the future, the transition to the microfabrication process of the logic circuit is an inevitable flow, and it is expected that the amount of allowable current Iₘₐₓ of the surge current path 59 decreases due to the miniaturization of the element size accompanying the circuit shrink. In other words, when the surge current path 59 is present in the pixel circuit, the amount of current flowing through the surge current path 59, that is, the amount of current required for ESD surge protection depends on the circuit configuration, size, and the like of the pixel circuit.

### <2. Embodiments of the Present Technology>

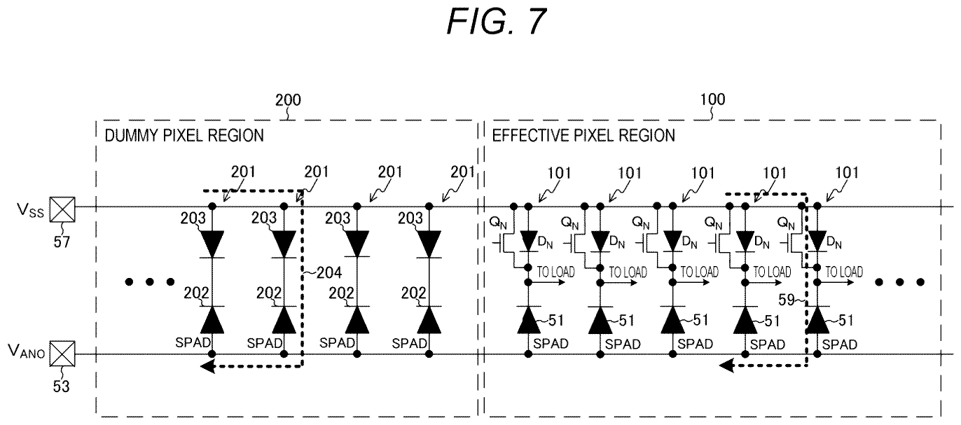

FIG. 7 is a circuit diagram schematically illustrating an embodiment of the present technology. In the embodiment of the present technology, for example, in the light receiving device 30 using the SPAD element as the light receiving element of the pixel, in order to be able to secure the amount of current necessary for ESD surge protection without depending on the circuit configuration, size, and the like of the pixel circuit, the following dummy pixel is utilized, and a surge current path (current path) for causing an ESD surge current to flow is formed in the dummy pixel using the light receiving element of the dummy pixel.

The pixel array section in the light receiving device 30 includes an effective pixel region 100 and a dummy pixel region 200. In the effective pixel region 100, effective pixels 101 that contribute to the detection of the presence or absence of photons, that is, contribute to the measurement of the time of flight of light are arranged in a matrix. In the dummy pixel region 200, dummy pixels 201 that do not contribute to the detection of the presence or absence of photons, that is, do not contribute to the measurement of the time of flight of light are arranged in a matrix.

An SPAD element 202 can also be used as the light receiving element of the dummy pixel 201, which is an example of a second light receiving element described in the claims, similarly to the light receiving element of the effective pixel 101, which is an example of the first light receiving element described in the claims. In the dummy pixel region 200, the dummy pixel 201 is arranged with low impedance from the terminal 53 to which the anode voltage V_{ANO} is provided or the terminal 57 to which the power supply voltage V_{SS} on the low potential side is provided.

In the embodiment of the present technology, by utilizing the SPAD element 202 which is a light receiving element of the dummy pixel 201 and connecting a diode element 203 in series to the SPAD element 202, a surge current path 204 (illustrated by a dotted line (thick line) arrow in FIG. 7) for causing an ESD surge current to flow is formed in the dummy pixel 201.

Specifically, in the dummy pixel 201, the SPAD element 202 and the diode element 203 are connected in series between a terminal 53 which is a first terminal to which the anode voltage V_{ANO} is applied and a terminal 57 which is a second terminal to which the power supply voltage V_{SS} on the low potential side is applied in a polarity relationship in the reverse direction to each other, thereby forming the surge current path 204. That is, the anode electrode of the SPAD element 202 is connected to the terminal 53, the cathode electrodes of the SPAD element 202 and the diode element 203 are commonly connected, and the anode electrode of the diode element 203 is connected to the terminal 57.

Here, the SPAD element 202 and the diode element 203 of the dummy pixel 201 forming the surge current path 204 constitute a protection circuit that protects the SPAD element 51 of the effective pixel 101 and the circuit element of the readout circuit of the effective pixel 101 from overvoltage, in particular, the ESD surge voltage in the reverse direction of the SPAD element 51. As the diode element 203, in addition to a general diode, a diode-connected transistor or the like can be exemplified.

As described above, in the embodiment of the present technology, the dummy pixel 201 existing outside the effective pixel region 100 is utilized, and the surge current path 204 is formed in the dummy pixel 201 using the SPAD element 202 of the dummy pixel 201. Therefore, the amount of current necessary for ESD surge protection can be secured without depending on the circuit configuration, size, and the like of the pixel circuit of the effective pixel 101 (specifically, the readout circuit of the effective pixel 101).

Here, the reason why the surge current path 204 of the dummy pixel 201 does not operate during the normal operation of each effective pixel 101 in the effective pixel region 100 will be described.

The SPAD element has temperature characteristics. By variably controlling the anode voltage V_{ANO} applied to the terminal 53 according to the temperature along the temperature characteristic of the SPAD element, the withstand voltage between the anode voltage V_{ANO} and the logic circuit (pixel readout circuit) is secured.

Assuming that the breakdown voltage V_{BD} of the SPAD element is 20 V, the voltage of V_{SS}−V_{ANO} is set to about 20 V in the normal operation. On the other hand, when the forward voltage of the diode is V_{f}, the withstand voltage of each path of the surge current path 59 in the effective pixel 101 and the surge current path 204 in the dummy pixel 201 is about 20+V_{f}. As described above, since the withstand voltage of each of the surge current paths 59 and 204 is larger than the voltage of V_{SS}−V_{ANO}, the surge current path 204 of the dummy pixel 201 does not operate during the normal operation of the effective pixel 101.

For the above reason, when the surge current path 204 is formed in the dummy pixel 201 using the SPAD element 202 of the dummy pixel 201, it is necessary to connect the diode element 203 in series to the SPAD element 202.

According to the protection circuit of the embodiment of the present technology, even if there is a variation in the breakdown voltage V_{BD} of the SPAD element,

[symbol] , the surge current path 204 of the dummy pixel 201 also operates in parallel when viewed transiently as described above. Therefore, there is no problem even if the surge current path 59 in the effective pixel 101 is turned on, and it may be considered as the total amount of current combined with the surge current path 204 of the dummy pixel 201. In practice, it is preferable to secure the number satisfying the criterion only by the amount of current of the surge current path 204 of the dummy pixel 201.

Hereinafter, a specific example of the embodiment of the present technology for securing an amount of current necessary for ESD surge protection by forming the surge current path 204 using the SPAD element 202 of the dummy pixel 201 without depending on the circuit configuration, size, and the like of the pixel circuit of the effective pixel 101 will be described.

### First Example

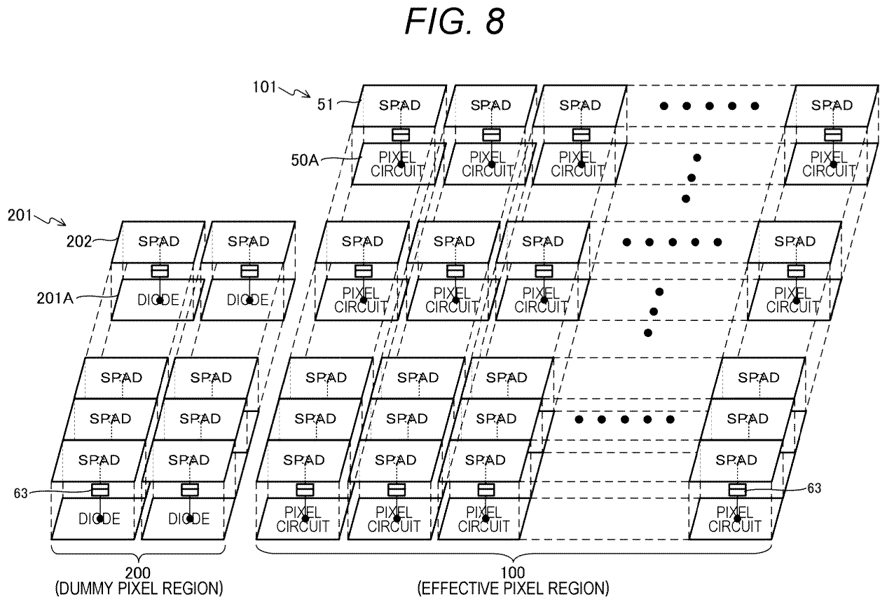

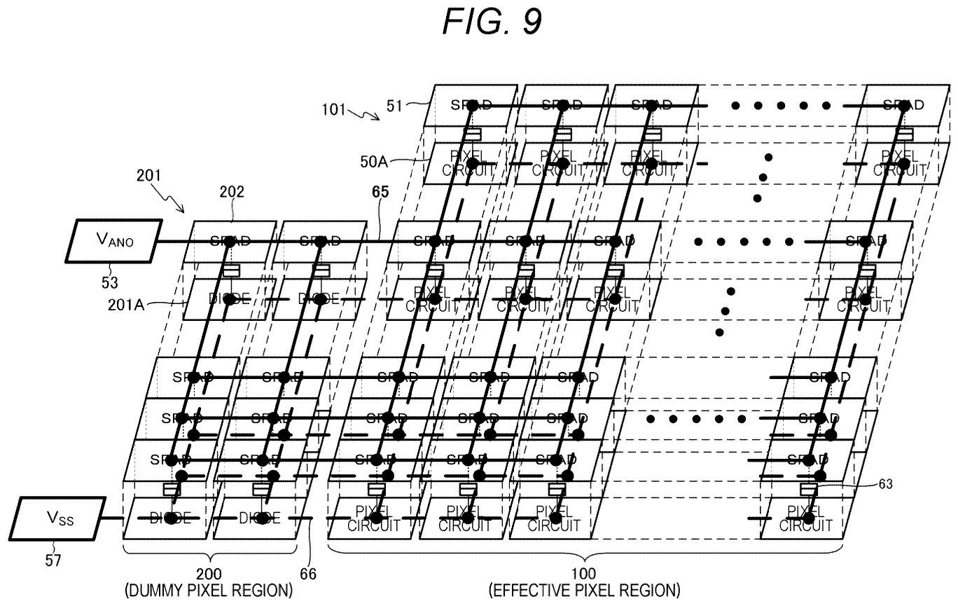

A first example of the embodiment of the present technology is an example in which the semiconductor chip structure of the light receiving device 30 is a stacked semiconductor chip structure. FIG. 8 is a perspective view schematically illustrating a configuration of a pixel array section in the light receiving device 30 according to the first example in the embodiment of the present technology, and FIG. 9 is a perspective view schematically illustrating a wiring structure of the pixel array section in the light receiving device 30 according to the first example.

As illustrated in FIGS. 8 and 9, the pixel array section of the light receiving device 30 according to the first example includes, in a stacked semiconductor chip structure, an effective pixel region 100 in which effective pixels 101 are arranged in a matrix, and a dummy pixel region 200 in which dummy pixels 201 are arranged in a matrix.

In the stacked semiconductor chip structure, in the effective pixel region 100, the SPAD element 51 is formed on the first semiconductor substrate 61 (see a in FIG. 5), and the readout circuit (logic circuit) 50A of the effective pixel 101 paired with the SPAD element 51 is formed on the second semiconductor substrate 62 (see a in FIG. 5) in the same size as the formation region of the SPAD element 51.

Similarly, in the dummy pixel region 200, the SPAD element 202 is formed on the first semiconductor substrate 61, and a circuit formation region 201A paired with the SPAD element 202 is formed on the second semiconductor substrate 62 in the same size as the formation region of the SPAD element 202. In general, in the circuit formation region 201A of the dummy pixel 201, a logic circuit similar to the readout circuit 50A of the effective pixel 101 is formed, but may not be formed.

In the stacked semiconductor chip structure described above, in the light receiving device 30 according to the first example, when the surge current path 204 is formed using the SPAD element 202 of the dummy pixel 201, the diode element 203 connected in series to the SPAD element 202 is formed in the circuit formation region 201A paired with the SPAD element 202 by changing to a logic circuit similar to the readout circuit 50A of the effective pixel 101.

In the stacked semiconductor chip structure, the circuit formation region 201A paired with the SPAD element 202 corresponds to a circuit formation region paired with the SPAD element 51, that is, a region in which the readout circuit (logic circuit) 50A of the effective pixel 101 paired with the SPAD element 51 is formed, and has a size similar to that of the circuit formation region of the readout circuit 50A. In this manner, the diode element 203 is formed as a single circuit element in the circuit formation region 201A having the size similar to that of the circuit formation region of the readout circuit 50A of the effective pixel 101.

Therefore, it is possible to form the diode element 203 having an extremely large size as compared with a case where a diode is formed as a single circuit element in the readout circuit 50A of the effective pixel 101. Then, since the size of the diode element 203 can be increased, the allowable current of one pair of the SPAD element 202 and the diode element 203 can be set to be large, so that a larger amount of current can be secured as the amount of current necessary for ESD surge protection flowing through the surge current path 204.

As illustrated in FIG. 9, the terminal 53 to which the anode voltage V_{ANO} is applied, and each anode electrode of the SPAD element 51 of the effective pixel 101 and each anode electrode of the SPAD element 202 of the dummy pixel 201 are electrically connected by a wiring 65. Furthermore, the terminal 57 to which the power supply voltage V_{SS} on the low potential side is applied and the anode electrode of each diode element 203 of the N-type MOS transistor ON and the dummy pixel 201 in the readout circuit (logic circuit) 50A of the effective pixel 101 are electrically connected by a wiring 66.

As described above, in the light receiving device 30 according to the first example, in the stacked semiconductor chip structure, the diode element 203 that is connected in series to the SPAD element 202 of the dummy pixel 201 to form the surge current path 204 is formed as a diode element having a large size in the circuit formation region 201A below the SPAD element 202. Therefore, a larger amount of current can be secured as the amount of current required for ESD surge protection flowing through the surge current path 204.

### Second Example

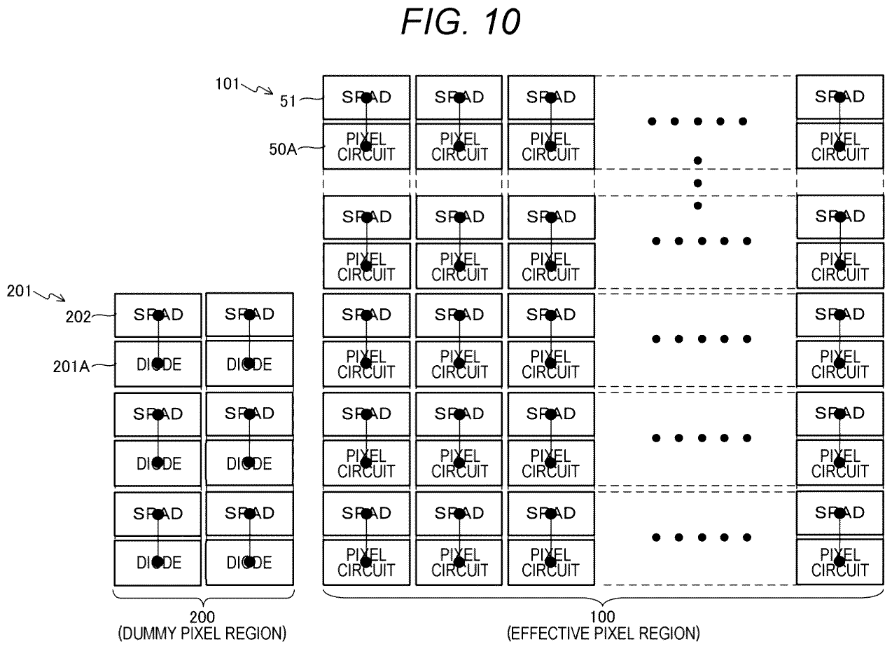

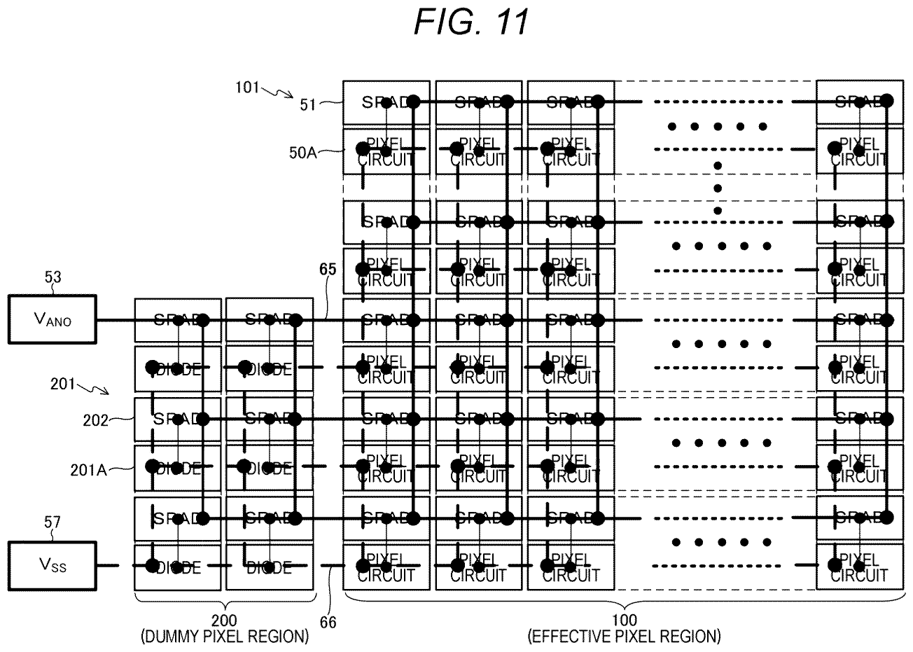

A second example of the embodiment of the present technology is an example in which the semiconductor chip structure of the light receiving device 30 is a flat semiconductor chip structure. FIG. 10 is a plan view schematically illustrating a configuration of a pixel array section in the light receiving device 30 according to the second example in the embodiment of the present technology, and FIG. 11 is a plan view schematically illustrating a wiring structure of the pixel array section in the light receiving device 30 according to the second example.

As illustrated in FIGS. 10 and 11, the pixel array section of the light receiving device 30 according to the second example includes, in a flat semiconductor chip structure, an effective pixel region 100 in which effective pixels 101 are arranged in a matrix, and a dummy pixel region 200 in which dummy pixels 201 are arranged in a matrix.

In the flat semiconductor chip structure, in the effective pixel region 100, the readout circuit (logic circuit) 50A of the effective pixel 101 paired with the SPAD element 51 is provided adjacent to the formation region with a size similar to that of the formation region of the SPAD element 51. Similarly, in the dummy pixel region 200, the circuit formation region 201A paired with the SPAD element 202 is provided adjacent to the formation region of the SPAD element 202 in a size similar to that of the formation region. In general, in the circuit formation region 201A of the dummy pixel 201, a logic circuit similar to the readout circuit 50A of the effective pixel 101 is formed, but may not be formed.

In the flat semiconductor chip structure described above, in the light receiving device 30 according to the second example, when the surge current path 204 is formed using the SPAD element 202 of the dummy pixel 201, the diode element 203 connected in series to the SPAD element 202 is formed in the circuit formation region 201A paired with the SPAD element 202 by changing to a logic circuit similar to the readout circuit 50A of the effective pixel 101.

In the flat semiconductor chip structure, the circuit formation region 201A paired with the SPAD element 202 corresponds to a circuit formation region of the readout circuit (logic circuit) 50A of the effective pixel 101 paired with the SPAD element 51, and has a size similar to that of the circuit formation region. In this manner, the diode element 203 is formed as a single circuit element in the circuit formation region 201A having the size similar to that of the circuit formation region of the readout circuit 50A of the effective pixel 101.

Therefore, it is possible to form the diode element 203 having an extremely large size as compared with a case where a diode is formed as a single circuit element in the readout circuit 50A of the effective pixel 101. Then, since the size of the diode element 203 can be set large, a larger amount of current can be secured as the amount of current necessary for ESD surge protection flowing in the surge current path 204 formed using the diode element 203.

As illustrated in FIG. 11, the terminal 53 to which the anode voltage V_{ANO} is applied, and each anode electrode of the SPAD element 51 of the effective pixel 101 and each anode electrode of the SPAD element 202 of the dummy pixel 201 are electrically connected by a wiring 65. Furthermore, the terminal 57 to which the power supply voltage V_{SS} on the low potential side is applied and the anode electrode of each diode element 203 of the N-type MOS transistor ON and the dummy pixel 201 in the readout circuit (logic circuit) 50A of the effective pixel 101 are electrically connected by a wiring 66.

As described above, in the light receiving device 30 according to the second example, in the flat semiconductor chip structure, the diode element 203 that is connected in series to the SPAD element 202 of the dummy pixel 201 to form the surge current path 204 is formed as a diode element having a large size in the circuit formation region 201A paired with the SPAD element 202. Therefore, a larger amount of current can be secured as the amount of current required for ESD surge protection flowing through the surge current path 204.

### Third Example

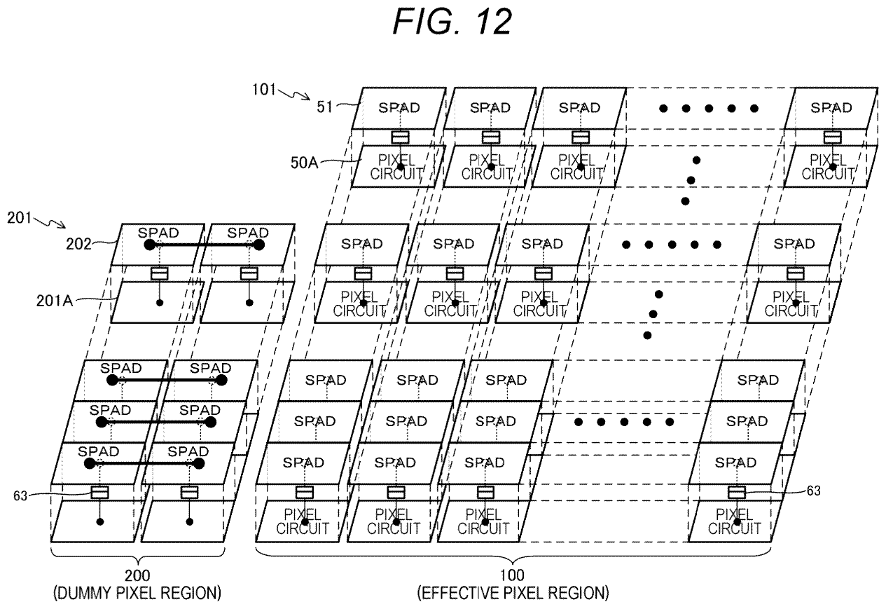

A third example of the embodiment of the present technology is an example in which a SPAD element of a dummy pixel adjacent to a dummy pixel to which the SPAD element belongs is used as a diode element forming a surge current path. FIG. 12 is a perspective view schematically illustrating a configuration of a pixel array section in the light receiving device 30 according to the third example in the embodiment of the present technology.

Here, a case where SPAD elements of adjacent dummy pixels are used as the diode element 203 forming the surge current path 204 on the premise of a stacked semiconductor chip structure will be described as an example of the light receiving device 30 according to the third example. However, the present invention is not limited to the stacked semiconductor chip structure, and the similar configuration can be adopted also in the flat semiconductor chip structure.

In the dummy pixel 201, a logic circuit similar to the readout circuit (logic circuit) 50A of the effective pixel 101 may be formed or may not be formed for the circuit formation region 201A paired with the SPAD element 202. FIG. 12 illustrates a case where a logic circuit similar to the readout circuit 50A of the effective pixel 101 is not formed in the circuit formation region 201A.

Here, the two dummy pixels 201 and 201 adjacent in the row direction of the pixel array in a matrix are paired to form the surge current path 204, but the present invention is not limited thereto, and the two dummy pixels 201 and 201 adjacent in the column direction may be paired to form the surge current path 204.

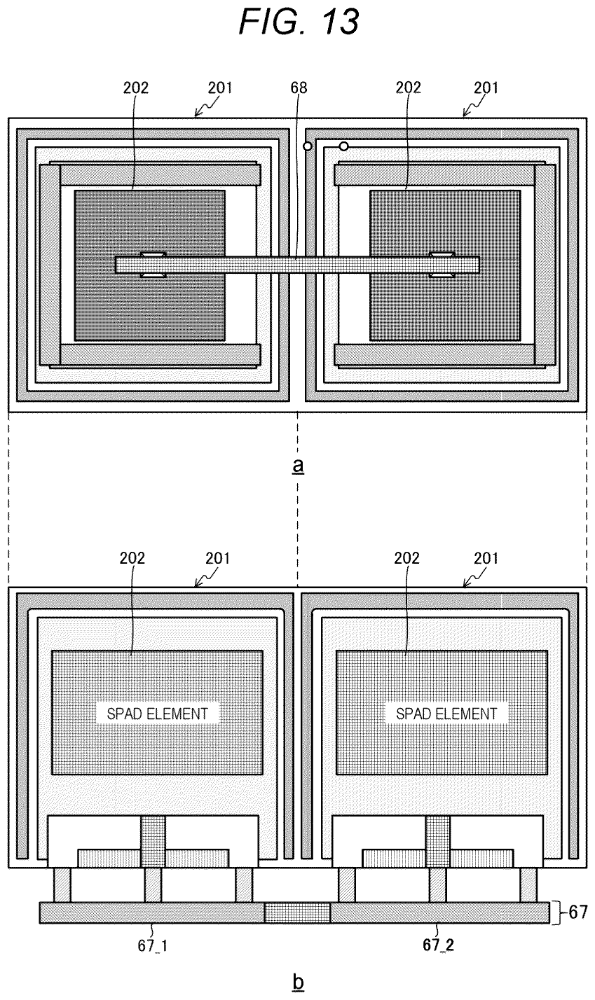

FIG. 13 is an explanatory diagram of two adjacent dummy pixels in the light receiving device 30 according to the third example. a of FIG. 13 is a plan view of two dummy pixels, and b of FIG. 13 is a cross-sectional view of the two dummy pixels.

In the respective SPAD elements 202 and 202 of the two dummy pixels 201 and 201 adjacent in the row direction, the respective anode electrodes are connected to the terminals 53 and 57 (see FIG. 7) via wirings 67_1 and 67_2 of a wiring layer 67. Furthermore, the cathode electrodes of the two SPAD elements 202 and 202 are electrically connected by a wiring 68. With this connection structure, the two SPAD elements 202 and 202 have the electrical connection relationship illustrated in FIG. 7, and one of them becomes the diode element 203.

As described above, in the light receiving device 30 according to the third example, as the diode element 203 connected in series to the SPAD element 202 of the dummy pixel 201 to form the surge current path 204, the SPAD element 202 of the dummy pixel 201 adjacent to the dummy pixel to which the light receiving device belongs is used. Therefore, it is not necessary to newly form the diode element 203 as in the case of the first example and the second example, and it is possible to form a desired surge current path 204 only by adding the wiring 67 or changing the circuit formation region 201A, and to secure the amount of current necessary for ESD surge protection.

### Fourth Example

In the light receiving device 30 according to the first to third examples described above, it is assumed that the protection circuit according to the reference example illustrated in FIG. 6, that is, the protection circuit including the high withstand voltage protection element 56 and the logic circuit protection circuit 58 is provided in the pixel circuit, but this is not essential. That is, although the logic circuit protection circuit 58 cannot be omitted, in the protection circuit using the SPAD element 202 of the dummy pixel 201, the high withstand voltage protection element 56 can be made unnecessary by devising the circuit configuration.

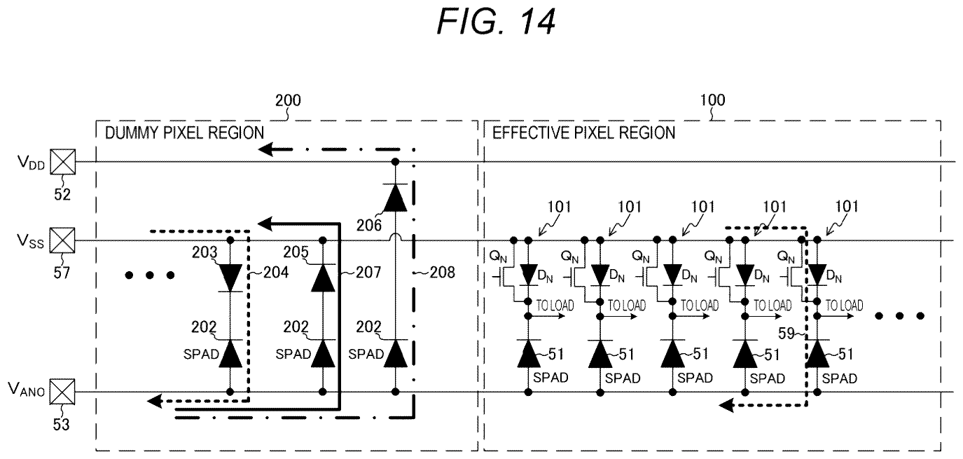

The fourth example of the embodiment of the present technology is an example in which the high withstand voltage protection element 56 provided in the pixel circuit is unnecessary. FIG. 14 is a circuit diagram schematically illustrating a circuit configuration example of a protection circuit of the light receiving device 30 according to the fourth example in the embodiment of the present technology.

As illustrated in FIG. 14, the protection circuit in the light receiving device 30 according to the fourth example has a configuration including two diode elements 205 and 206 formed using two dummy pixels 201 and 201 adjacent to the dummy pixel 201 including the SPAD element 202, in addition to the diode element 203 connected in series to the SPAD element 202 in a polarity relationship in the reverse direction.

The diode element 203 is connected in series to the SPAD element 202 in a polarity relationship in the reverse direction between the cathode electrode of the SPAD element 202 of the dummy pixel 201 to which the diode element belongs and the terminal 57 to which the power supply voltage V_{SS} on the low potential side is applied, thereby forming the surge current path 204 (illustrated by a dotted line (thick line) arrow in FIG. 14). As described above, the surge current path 204 protects the SPAD element 51 of the effective pixel 101 and the circuit element of the readout circuit of the effective pixel 101 from the ESD surge voltage in the reverse direction of the SPAD element 51.

The diode element 205 is connected in series to the SPAD element 202 in a polarity relationship in the forward direction between the cathode electrode of the SPAD element 202 of the dummy pixel 201 to which the diode element belongs and the terminal 57 to which the power supply voltage V_{SS} on the low potential side is applied, thereby forming a surge current path 207 (illustrated by a solid line (thick line) arrow in FIG. 14). The surge current path 207 protects the SPAD element 51 of the effective pixel 101 and the circuit element of the readout circuit of the effective pixel 101 from the ESD surge voltage in the forward direction of the SPAD element 51.

The diode element 206 is connected in series to the SPAD element 202 in a polarity relationship in the forward direction between the cathode electrode of the SPAD element 202 of the dummy pixel 201 to which the diode element belongs and the terminal 52 to which the power supply voltage V_{DD} on the high potential side is applied, thereby forming a surge current path 208 (illustrated by a dotted line (thick line) arrow in FIG. 14). The surge current path 208 protects the SPAD element 51 of the effective pixel 101 and the circuit element of the readout circuit of the effective pixel 101 from the ESD surge voltage in the forward direction of the SPAD element 51.

As described above, the three surge current paths, that is, the surge current path 204, the surge current path 207, and the surge current path 208 can be formed using three dummy pixels adjacent to each other as one group.

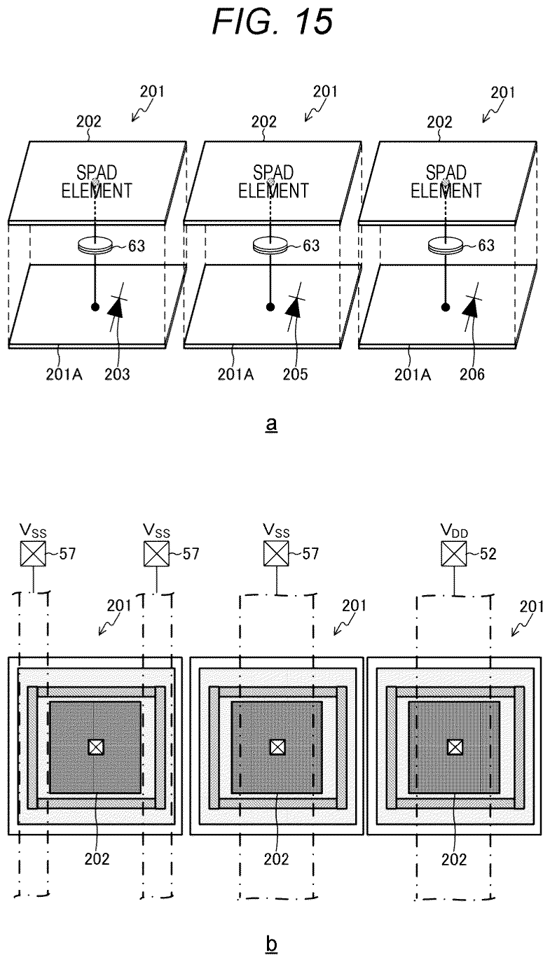

FIG. 15 illustrates a configuration example in which three surge current paths 204, 207, and 208 are formed with three dummy pixels adjacent to each other as one group in the light receiving device 30 according to the fourth example. FIG. 15 illustrates three dummy pixels of a certain group in the dummy pixel region 200. Here, the case of the stacked semiconductor chip structure is exemplified, but the present invention is not limited to the stacked semiconductor chip structure. a of FIG. 15 is a perspective view of three dummy pixels, and b of FIG. 15 is a plan view of the three dummy pixels.

The diode element 203 that is connected in series to the SPAD element 202 of the dummy pixel 201 in a polarity relationship in the reverse direction to form the surge current path 204 is formed as a single circuit element in the circuit formation region 201A paired with the SPAD element 202, that is, as a large-sized diode element, as in the case of the first example.

The diode elements 205 and 206 connected in series to the SPAD elements 202 of the dummy pixels 201 in the polarity relationship in the forward direction to form the surge current paths 207 and 208 are respectively formed as logic diode elements in the circuit formation regions 201A and 201A located below the element region in the other two dummy pixels 201 and 201. The electrical connection relationship of the diode elements 205 and 206 is as illustrated in FIG. 14.

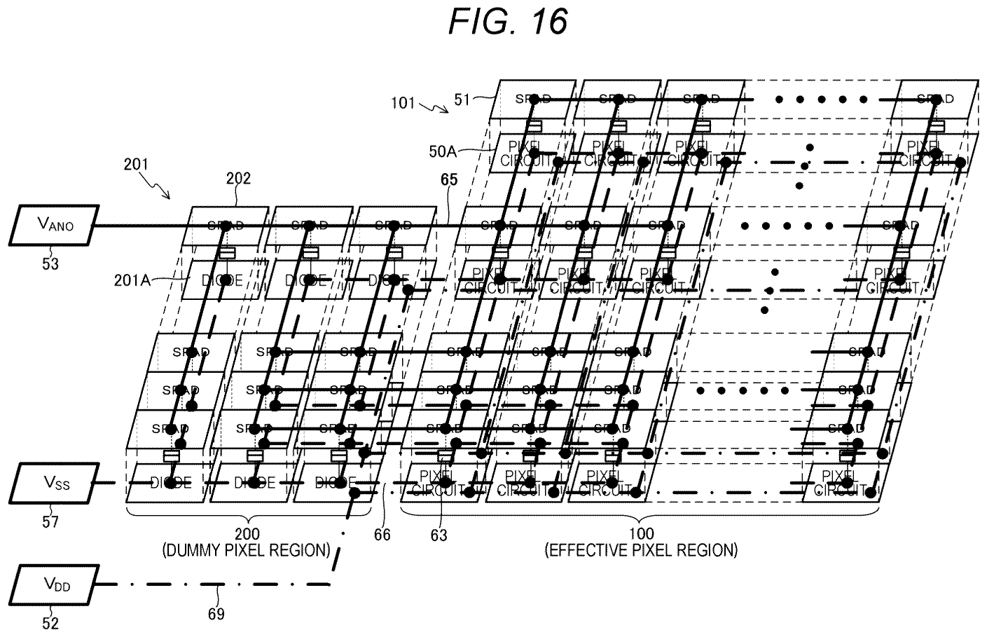

FIG. 16 schematically illustrates a wiring structure of the pixel array section in the light receiving device 30 according to the fourth example.

As described above, the light receiving device 30 according to the fourth example includes two surge current paths 207 and 208 in addition to the surge current path 204 including the diode element 203 connected in series to the SPAD element 202 in a polarity relationship in the reverse direction. The two surge current paths 207 and 208 include the SPAD elements 202 and 202 belonging to the dummy pixels 201 and 201 to which the two surge current paths belong, and the diode elements 205 and 206 connected in series to the SPAD elements 202 and 202 in a polarity relationship in the forward direction.

Since the above-described two surge current paths 207 and 208 can protect the SPAD element 51 of the effective pixel 101 and the circuit element of the readout circuit of the effective pixel 101 from the ESD surge voltage in the forward direction of the SPAD element 51, the high withstand voltage protection element 56 used in the protection circuit (see FIG. 6) according to the reference example becomes unnecessary. Then, the high withstand voltage protection element 56 is a circuit element provided for the plurality of effective pixels 101, and since the high withstand voltage protection element 56 can be omitted, an area on the chip occupied by the high withstand voltage protection element 56 becomes unnecessary, and cost reduction due to the unnecessary mask in the high withstand voltage process step can be achieved. Also in the light receiving device 30 according to the fourth example, it is a matter of course that the amount of current necessary for ESD surge protection can be secured by the action of the surge current path 204.

Note that, in the fourth example, the configuration in which the two surge current paths of the surge current paths 207 and 208 are simultaneously provided has been described as an example. However, even with the configuration in which one of the surge current paths 207 and 208 is provided, the SPAD element 51 of the effective pixel 101 and the circuit element of the readout circuit of the effective pixel 101 can be protected from the ESD surge voltage in the forward direction of the SPAD element 51.

### Fifth Example

A fifth example of the embodiment of the present technology is a modification of the fourth example, and is an example in which the SPAD element of the adjacent dummy pixel is used as the diode element forming the surge current path when the high withstand voltage protection element 56 provided in the pixel circuit is unnecessary.

The circuit configuration example of the protection circuit of the light receiving device 30 according to the fifth example of the embodiment of the present technology is the same as the circuit diagram of FIG. 14 schematically illustrating the circuit configuration example of the protection circuit of the light receiving device 30 according to the fourth example.

Specifically, the diode element 203 is connected in series to the SPAD element 202 in a polarity relationship in the reverse direction between the cathode electrode of the SPAD element 202 of the dummy pixel 201 to which the diode element belongs and the terminal 57 to which the power supply voltage V_{SS} on the low potential side is applied, thereby forming the surge current path 204 (illustrated by a dotted line (thick line) arrow in FIG. 14).

The diode element 205 is connected in series to the SPAD element 202 in a polarity relationship in the forward direction between the cathode electrode of the SPAD element 202 of the dummy pixel 201 to which the diode element belongs and the terminal 57 to which the power supply voltage V_{SS} on the low potential side is applied, thereby forming a surge current path 207 (illustrated by a solid line (thick line) arrow in FIG. 14).

The diode element 206 is connected in series to the SPAD element 202 in a polarity relationship in the forward direction between the cathode electrode of the SPAD element 202 of the dummy pixel 201 to which the diode element belongs and the terminal 52 to which the power supply voltage V_{DD} on the high potential side is applied, thereby forming a surge current path 208 (illustrated by a dotted line (thick line) arrow in FIG. 14).

In the fourth example, with three dummy pixels adjacent to each other as one group, the diode elements 203, 205, and 206 forming the surge current paths 204, 207, and 208 are formed in a circuit formation region paired with the SPAD element in each dummy pixel. On the other hand, in the fifth example, similarly to the case of the third example, the SPAD elements of the adjacent dummy pixel are used as the diode elements 203, 205, and 206 forming the surge current paths 204, 207, and 208. In this case, six dummy pixels adjacent to each other are treated as one group.

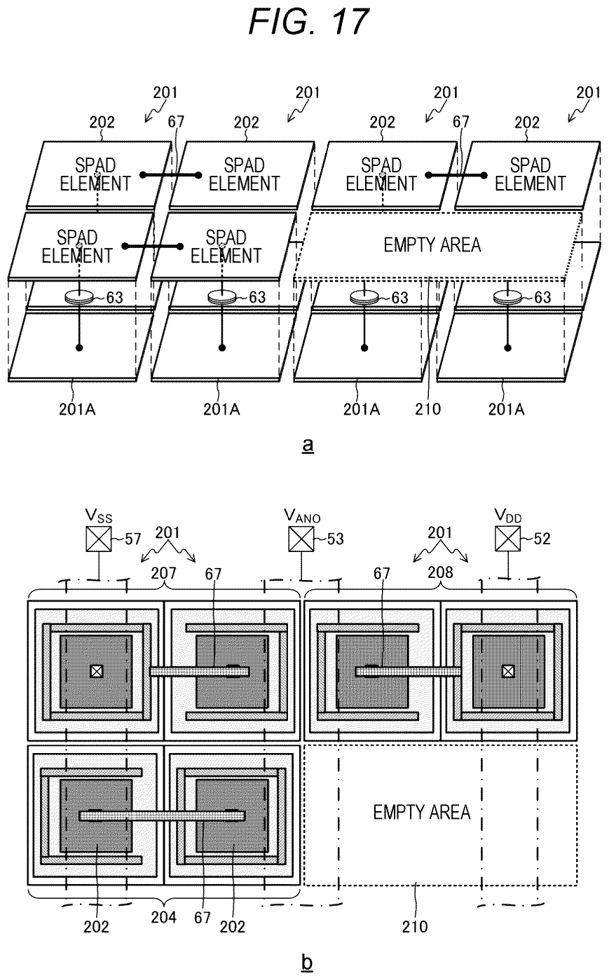

FIG. 17 illustrates a configuration example in which three surge current paths 204, 207, and 208 are formed with six dummy pixels adjacent to each other as one group in the light receiving device 30 according to the fifth example. FIG. 17 illustrates six dummy pixels of one group in the dummy pixel region 200. Here, the case of the stacked semiconductor chip structure is exemplified, but the present invention is not limited to the stacked semiconductor chip structure. a of FIG. 17 is a perspective view of three dummy pixels, and b of FIG. 17 is a plan view of the three dummy pixels.

For six dummy pixels in one group, three pairs of adjacent two dummy pixels 201 and 201 are provided as one pair over two adjacent rows as illustrated in a and b of FIG. 17. For these three pairs, in comparison with the circuit diagram of FIG. 14 illustrating the surge current paths 204, 207, and 208, one pair in the upper left of the drawing forms the surge current path 207, one pair in the upper right of the drawing forms the surge current path 208, and one pair in the lower left of the drawing forms the surge current path 204.

For six dummy pixels of one group, three pairs of adjacent two dummy pixels 201 and 201 are provided as one pair over two adjacent rows, whereby an empty area 210 corresponding to one pair is generated in the lower right of the drawing. The empty area 210 may be filled by, for example, copying one pair in the upper right of the drawing connected to the terminal 52 to which the power supply voltage V_{DD} on the high potential side is applied.

As described above, in the light receiving device 30 according to the fifth example, in order to eliminate the need for the high withstand voltage protection element 56 provided in the pixel circuit, the SPAD elements of the adjacent dummy pixel are used as the diode elements 203, 205, and 206 forming the surge current paths 204, 207, and 208. Therefore, the surge current paths 204, 207, and 208 can be formed only by adding the wiring 67 or changing the circuit formation region 201A while eliminating the need for the high withstand voltage protection element 56, and the amount of current necessary for ESD surge protection can be secured.

### Sixth Example

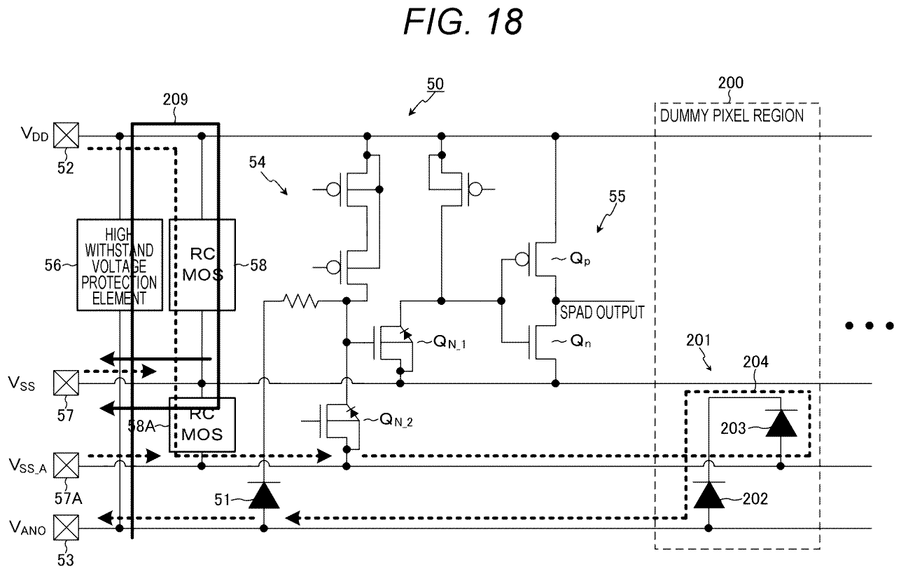

A sixth example of the embodiment of the present technology is an example in which the pixel circuit includes a thin film transistor. By forming the pixel circuit (that is, the logic circuit) with a thin film transistor having a gate oxide film, the area of the pixel circuit can be reduced. FIG. 18 is a circuit diagram schematically illustrating a circuit configuration example of a pixel circuit and a dummy pixel of the light receiving device 30 according to the sixth example in the embodiment of the present technology.

In a case where the readout circuit (pixel circuit) of the pixel 50 includes a thin film transistor, two systems of power supplies on the low potential side are provided. Specifically, in addition to the power supply voltage V_{SS} provided to the terminal 57, a power supply voltage V_{SS_A} provided to a terminal 57A is used.

As an example, in a case where the power supply voltage V_{SS} is set to 0 V, a negative voltage value is set as the power supply voltage V_{SS_A}. Accordingly, the anode voltage V_{ANO} provided to the terminal 53 is set to a voltage value lower by the voltage value of the power supply voltage V_{SS_A} than the negative voltage value when the power supply voltage V_{SS_A} is not used. Similarly, the power supply voltage V_{DD} on the high potential side is also set to a voltage value lower by the voltage value of the power supply voltage V_{SS_A} than the positive voltage value when the power supply voltage V_{SS_A} is not used.

Furthermore, in the pixel circuit including the thin film transistor, as the protection circuit, a logic circuit protection circuit 58A connected between the terminal 57 and the terminal 57A is provided in addition to the high withstand voltage protection element 56 connected between the terminal 52 and the terminal 53 and the logic circuit protection circuit 58 connected between the terminal 52 and the terminal 57.

Also in the light receiving device 30 in which the pixel circuit is configured using a thin film transistor, the surge current path 204 (illustrated by a dotted line (thick line) arrow in FIG. 18) for causing an ESD surge current to flow is formed in the dummy pixel 201 by utilizing the SPAD element 202 of the dummy pixel 201 and connecting the diode element 203 in series to the SPAD element 202.

In FIG. 18, the surge current path 204 indicated by a dotted line (thick) arrow is for protecting the SPAD element 51 of the effective pixel 101 and the circuit element of the readout circuit of the effective pixel 101 against the ESD surge voltage in the reverse direction of the SPAD element 51. For the protection against the ESD surge voltage in the forward direction of the SPAD element 51, a surge current path 209 indicated by a solid line (thick line) arrow including the high withstand voltage protection element 56 functions.

As described above, in the light receiving device 30 according to the sixth example, even in the light receiving device 30 in which the pixel circuit is configured using the thin film transistor, the amount of current necessary for ESD surge protection flowing in the surge current path 204 can be secured by forming the surge current path 204 by utilizing the dummy pixel 201.

### Seventh Example

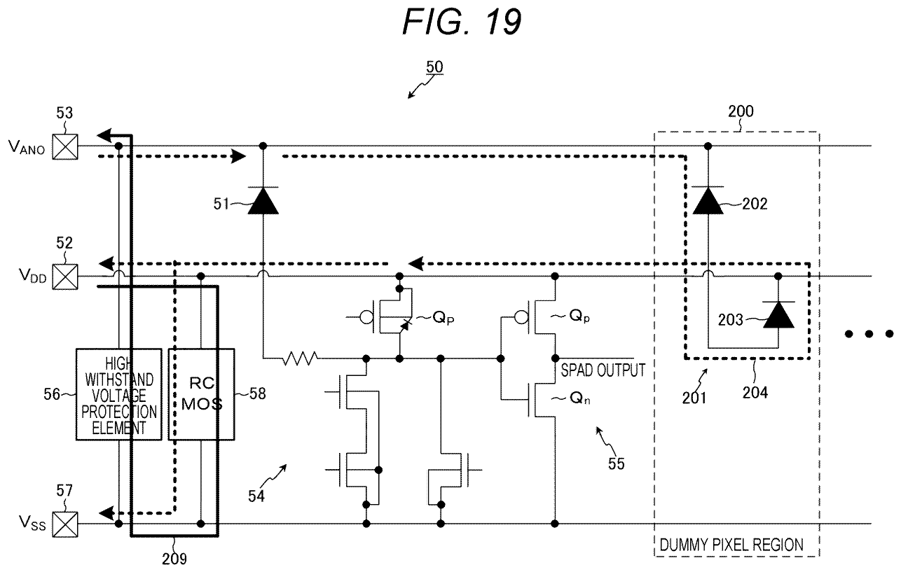

A seventh example of the embodiment of the present technology is an example in which the polarity of the voltage applied to the SPAD element is inverted in the pixel circuit. FIG. 19 is a circuit diagram schematically illustrating a circuit configuration example of a pixel circuit and a dummy pixel of the light receiving device 30 according to the seventh example in the embodiment of the present technology.

In the light receiving devices 30 according to the first to sixth examples, a large negative voltage is applied as the anode voltage to the SPAD element 51. On the other hand, in the light receiving device 30 according to the seventh example, a large positive voltage is applied as the cathode voltage to the SPAD element 51. Correspondingly, the conductivity type of each transistor constituting the pixel circuit is a reverse conductivity type (P type→N type, N type→P type). The pixel circuit having this circuit configuration is a so-called anode readout type pixel circuit.

In the circuit diagram of FIG. 19, the surge current path 204 indicated by a dotted line (thick) arrow is a path for protecting the SPAD element 51 of the effective pixel 101 and the circuit element of the readout circuit of the effective pixel 101 against the ESD surge voltage in the reverse direction of the SPAD element 51. Furthermore, the surge current path 209 indicated by a solid line (thick line) arrow including the high withstand voltage protection element 56 is a path for protection against the ESD surge voltage in the forward direction of the SPAD element 51.

As described above, in the light receiving device 30 according to the seventh example, even in the light receiving device 30 having the anode readout type pixel circuit of the anode readout type that applies a large positive voltage as the cathode voltage to the SPAD element 51, the amount of current necessary for ESD surge protection flowing in the surge current path 204 can be secured by utilizing the dummy pixel 201.

### <3. Modifications>

Note that the embodiments described above show examples for embodying the present technology, and the matters in the embodiments and the matters specifying the invention in the claims have corresponding relationships, respectively. Similarly, the matters specifying the invention in the claims and matters with the same names in the embodiments of the present technology have correspondence relationships. However, the present technology is not limited to the embodiments and may be embodied by variously modifying the embodiments without departing from the scope thereof.

### <4. Example of Application to Mobile Object>

The technology according to the present disclosure (the present technology) can be applied to various products. For example, the technology according to the present disclosure may be implemented in a form of a device to be mounted to a mobile object of any type such as an automobile, an electric vehicle, a hybrid electric vehicle, a motorcycle, a bicycle, a personal mobility, an airplane, a drone, a ship, and a robot.

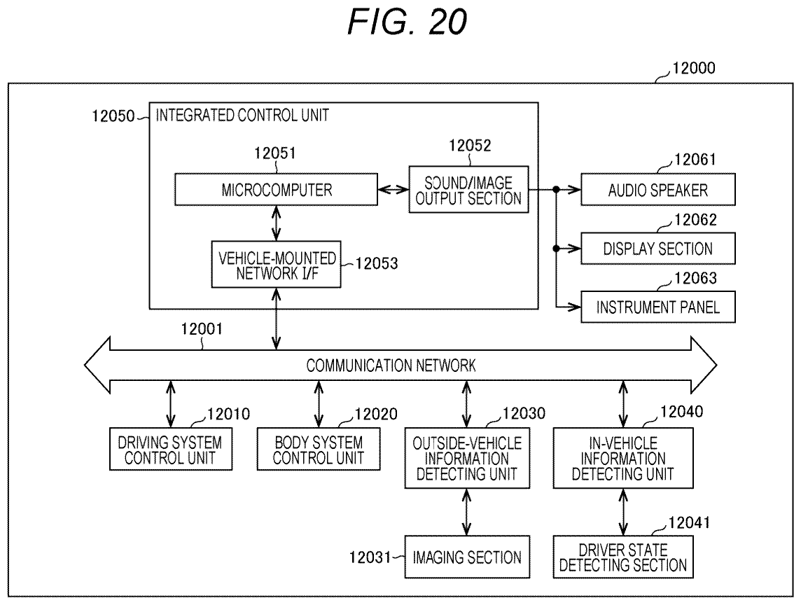

FIG. 20 is a block diagram depicting an example of schematic configuration of a vehicle control system as an example of a mobile object control system to which the technology according to an embodiment of the present disclosure can be applied.

The vehicle control system 12000 includes a plurality of electronic control units connected to each other via a communication network 12001. In the example illustrated in FIG. 20, the vehicle control system 12000 includes a driving system control unit 12010, a body system control unit 12020, an outside-vehicle information detecting unit 12030, an in-vehicle information detecting unit 12040, and an integrated control unit 12050. Furthermore, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs.

For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

Furthermore, the microcomputer 12051 can output a control command to the body system control unit 12020 on the basis of the information about the outside of the vehicle acquired by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 20, an audio speaker 12061, a display section 12062, and an instrument panel 12063 are exemplified as the output device. The display section 12062 may, for example, include at least one of an on-board display and a head-up display.

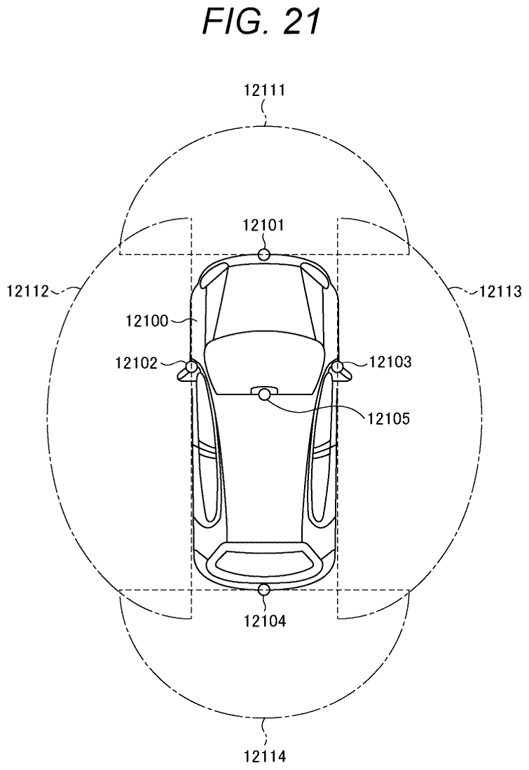

FIG. 21 is a diagram depicting an example of the installation position of the imaging section 12031.

In FIG. 21, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100.

The imaging section 12105 provided to the upper portion of the windshield within the interior of the vehicle is used mainly to detect a preceding vehicle, a pedestrian, an obstacle, a signal, a traffic sign, a lane, or the like.

Note that FIG. 21 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the vehicle control system to which the technology according to the present disclosure can be applied has been described above. The technology according to the present disclosure can be applied to, for example, the imaging section 12031 among the constituents described above. Specifically, the distance measuring device including the light receiving device according to each example in the above-described embodiment can be applied to the imaging section 12031. By applying the technology according to the present disclosure to the imaging section 12031, it is possible to secure the amount of current necessary for ESD surge protection without depending on the circuit configuration, size, and the like of the pixel circuit of the effective pixel 101, and thus, it is possible to reliably protect the circuit element constituting the pixel circuit from the ESD surge.

Note that, the effects described in this specification are merely examples, and are not limited to them; there may also another effect.

### <5. Configuration That Present Technology can Employ>

Note that the present technology may also have the following configurations.

(1) A light device including:
an effective pixel including a light receiving element that detects presence or absence of photons and a readout circuit of a pixel which processes a signal output from the light receiving element;
a dummy pixel including a light receiving element that does not contribute to detection of presence or absence of photons;
a first terminal configured to apply a predetermined voltage to a light receiving element of the effective pixel and a light receiving element of the dummy pixel;
a second terminal configured to provide a first power supply voltage to the readout circuit; and
a protection circuit including a diode element connected between a light receiving element of the dummy pixel and the second terminal in a polarity relationship in a reverse direction with respect to a light receiving element of the dummy pixel, and protecting a light receiving element of the effective pixel and a circuit element of the readout circuit from overvoltage.

(2) The light receiving device according to (1), in which
in the effective pixel, a readout circuit of the pixel is formed in a pixel formation region paired with the light receiving element, and
in the dummy pixel, the diode element is formed in a pixel formation region corresponding to the pixel formation region of the effective pixel.

(3) The light receiving device according to (1) or (2), in which
a light receiving element of the effective pixel and a light receiving element of the dummy pixel are avalanche diodes.

(4) The light receiving device according to (3), in which
a light receiving element of the effective pixel and a light receiving element of the dummy pixel are single photon avalanche diodes.

(5) The light receiving device according to (4), in which
a single photon avalanche diode of a dummy pixel adjacent to a dummy pixel to which the diode element belongs is used as the diode element.

(6) The light receiving device according to (4), further including:
a third terminal configured to apply a second power supply voltage to a readout circuit of the effective pixel; and
at least one of a surge current path including a diode element connected to a light receiving element of the dummy pixel in a polarity relationship in a forward direction between the first terminal and the second terminal or a surge current path including a diode element connected to a light receiving element of the dummy pixel in a polarity relationship in a forward direction between the first terminal and the third terminal.

(7) The light receiving device according to any one of (1) to (6), in which
a readout circuit of the effective pixel is configured using a thin film transistor.

(8) A light receiving device including:
a first light receiving element;
a quench element connected between a first node that is an anode or a cathode of the first light receiving element and a node of a first power supply voltage;
a transistor connected between a node of the first power supply voltage and a node of a second power supply voltage;
a second light receiving element; and
a diode element connected between a second node that is an anode or a cathode of the second light receiving element and a node of the second power supply voltage and connected to the second light receiving element in a polarity relationship in a reverse direction, in which
the first light receiving element and the second light receiving element receive a predetermined voltage at a node opposite to the first node and the second node.

(9) The light receiving device according to (8), in which
the first light receiving element is arranged in an effective pixel region, and
the second light receiving element is arranged in a dummy pixel region.

(10) The light receiving device according to (8) or (9), further including:
a first substrate including the first light receiving element and the second light receiving element; and
a second substrate including the quench element, the transistor, and the diode element.

(11) A distance measuring device including:
a light source unit that irradiates a distance measuring object with light; and
a light receiving device that receives reflected light from the distance measuring object based on irradiation light from the light source unit, in which
the light receiving device includes:
an effective pixel including a light receiving element that detects presence or absence of photons and a readout circuit of a pixel which processes a signal output from the light receiving element;
a dummy pixel including a light receiving element that does not contribute to detection of presence or absence of photons;
a first terminal configured to apply a predetermined voltage to a light receiving element of the effective pixel and a light receiving element of the dummy pixel;
a second terminal configured to apply a first power supply voltage to the readout circuit; and
a protection circuit including a diode element connected between a light receiving element of the dummy pixel and the second terminal in a polarity relationship in a reverse direction with respect to a light receiving element of the dummy pixel, and protecting a light receiving element of the effective pixel and a circuit element of the readout circuit from overvoltage.

### REFERENCE SIGNS LIST

1 Distance measuring device
10 Subject (distance measuring object)
20 Light source unit
21 Laser drive unit
22 Laser light source
23 Diffusion lens
30 Light receiving device
31 Light receiving lens
32 Optical sensor
33 Signal processing unit
40 Control unit
50 Pixel
50A Pixel readout circuit (logic circuit)
51 SPAD element
54 Quench element
55 CMOS inverter
56 High withstand voltage protection element
58, 58A Logic circuit protection circuit
59 Surge current path
61 First semiconductor substrate
62 Second semiconductor substrate
63 Wiring layer
64 Bonding portion such as Cu—Cu bonding
100 Effective pixel region
101 Effective pixel
200 Dummy pixel region
201 Dummy pixel
201A Circuit formation region
202 SPAD element
203, 205, 206 Diode element
204, 207, 208, 209 Surge current path

1. A light receiving device comprising:
an effective pixel including a light receiving element that detects presence or absence of photons and a readout circuit of a pixel which processes a signal output from the light receiving element;
a dummy pixel including a light receiving element that does not contribute to detection of presence or absence of photons;
a first terminal configured to apply a predetermined voltage to a light receiving element of the effective pixel and a light receiving element of the dummy pixel;
a second terminal configured to provide a first power supply voltage to the readout circuit; and
a protection circuit including a diode element connected between a light receiving element of the dummy pixel and the second terminal in a polarity relationship in a reverse direction with respect to a light receiving element of the dummy pixel, and protecting a light receiving element of the effective pixel and a circuit element of the readout circuit from overvoltage.

2. The light receiving device according to claim 1, further comprising:
a first substrate including a light receiving element of the effective pixel and a light receiving element of the dummy pixel; and
a second substrate including the readout circuit and the protection circuit.

3. The light receiving device according to claim 1, wherein
a light receiving element of the effective pixel and a light receiving element of the dummy pixel are avalanche diodes.

4. The light receiving device according to claim 3, wherein
a light receiving element of the effective pixel and a light receiving element of the dummy pixel are single photon avalanche diodes.

5. The light receiving device according to claim 4, wherein
a single photon avalanche diode of a dummy pixel adjacent to a dummy pixel to which the diode element belongs is used as the diode element.

6. The light receiving device according to claim 4, further comprising:
a third terminal configured to apply a second power supply voltage to a readout circuit of the effective pixel; and
at least one of a surge current path including a diode element connected to a light receiving element of the dummy pixel in a polarity relationship in a forward direction between the first terminal and the second terminal or a surge current path including a diode element connected to a light receiving element of the dummy pixel in a polarity relationship in a forward direction between the first terminal and the third terminal.

7. The light receiving device according to claim 1, wherein
a readout circuit of the effective pixel is configured using a thin film transistor.

8. A light receiving device comprising:
a first light receiving element;
a quench element connected between a first node that is an anode or a cathode of the first light receiving element and a node of a first power supply voltage;
a transistor connected between a node of the first power supply voltage and a node of a second power supply voltage;
a second light receiving element; and
a diode element connected between a second node that is an anode or a cathode of the second light receiving element and a node of the second power supply voltage and connected to the second light receiving element in a polarity relationship in a reverse direction, wherein
the first light receiving element and the second light receiving element receive a predetermined voltage at a node opposite to the first node and the second node.

9. The light receiving device according to claim 8, wherein
the first light receiving element is arranged in an effective pixel region, and
the second light receiving element is arranged in a dummy pixel region.

10. The light receiving device according to claim 8, further comprising:
a first substrate including the first light receiving element and the second light receiving element; and
a second substrate including the quench element, the transistor, and the diode element.

11. A distance measuring device comprising:
a light source unit that irradiates a distance measuring object with light; and
a light receiving device that receives reflected light from the distance measuring object based on irradiation light from the light source unit, wherein
the light receiving device includes:
an effective pixel including a light receiving element that detects presence or absence of photons and a readout circuit of a pixel which processes a signal output from the light receiving element;
a dummy pixel including a light receiving element that does not contribute to detection of presence or absence of photons;
a first terminal configured to apply a predetermined voltage to a light receiving element of the effective pixel and a light receiving element of the dummy pixel; and
a protection circuit including a diode element connected between a light receiving element of the dummy pixel and the second terminal in a polarity relationship in a reverse direction with respect to a light receiving element of the dummy pixel, and protecting a light receiving element of the effective pixel and a circuit element of the readout circuit from overvoltage.
